(19) United States
(12) Patent Application Publication
(10) Pub. No.: US 2019/0293596 A1
(43) Pub. Date: Sep. 26, 2019

(54) GAS SENSING METHOD, GAS SENSOR, AND GAS SENSING SYSTEM

(71) Applicant: KABUSHIKI KAISHA TOSHIBA, Minato-ku (JP)

(72) Inventors: Hiroko NAKAMURA, Yokohama (JP); Hideyuki NISHIZAWA, Toshima (JP); Kenji NAKAMURA, Kawasaki (JP)

(73) Assignee: KABUSHIKI KAISHA TOSHIBA, Minato-ku (JP)

(21) Appl. No.: 16/131,407

(22) Filed: Sep. 14, 2018

(30) Foreign Application Priority Data
Mar. 22, 2018 (JP) 2018-055023

(51) Int. Cl. G01N 27/414; H01L 29/06; G01R 27/26; G01N 27/22; H01L 29/423

(52) U.S. Cl. CPC G01N 27/4146; G01N 27/4141; H01L 29/42372; G01R 27/2605; G01N 27/226; H01L 29/0673

(57) ABSTRACT

The gas sensing method of an embodiment includes: a step of supplying measured gas to a capacitor including a first electrode, a dielectric formed to be electrically connected to the first electrode, a graphene formed on the dielectric, and a second electrode formed to be electrically connected to the graphene; and a step of measuring a capacitance of the capacitor after the measured gas is brought into contact with the graphene.

### CROSS REFERENCE TO RELATED APPLICATION

This application is based upon and claims the benefit of priority from Japanese Patent Application No. 2018-055023, filed on Mar. 22, 2018; the entire contents of which are incorporated herein by reference.

### FIELD

Embodiments described herein generally relate to a gas sensing method, a gas sensor, and a gas sensing system.

### BACKGROUND

Conventionally, various gas sensors have been proposed. For example, a capacitive sensor using carbon nanotubes (CNTs) has been known. In such a capacitive sensor, for example, a dielectric and the CNTs are stacked on a lower electrode, and a comb-shaped electrode is formed thereon. Since the CNTs are formed only at a surface, gas diffuses fast, and responsiveness is excellent. However, the CNT has a tubular shape, and a position control thereof is difficult, resulting in that the CNTs overlap with each other to generate gaps, and the dielectric is likely to be exposed. If the dielectric is exposed, measured gas enters the dielectric, to simultaneously measure a capacitance change due to a change of a dielectric constant resulting from the entered measured gas. Accordingly, there is a problem that sensitivity is lowered and response becomes slow.

As a gas sensor using graphene, there is known a gas sensor (GFET sensor) using a field-effect transistor (FET) where graphene is used as a channel. The GFET sensor includes a dielectric formed on a back gate electrode, and graphene, a source electrode, and a drain electrode provided on the dielectric. A conductance change with respect to a gate voltage takes a minimum value because graphene has two types of carriers of holes and electrons. For example, when the conductance is measured while supplying NO₂ to the GFET and changing the gate voltage, gas can be sensed from a conductance change amount based on increase in the holes if the voltage is set to be constant, because NO₂ functions as a p-type dopant.

However, since a drain current is passed through graphene in the GFET sensor, graphene is heated to cause temperature rise. Characteristics of the GFET change due to the temperature rise. In addition, a residual solvent and gas in the air are adsorbed to a surface of graphene, to be a doping state. Adsorbed substances are desorbed due to the heating of graphene, to cause a change in the number of carriers, resulting in that the characteristics of the GFET change. There is a problem that variation in the gas sensing becomes large in the conventional GFET due to these effects.

As another type of the gas sensor using graphene, there is known a sensor using an organic semiconductor FET (OFET) where graphene is used as a gate electrode of the organic semiconductor. Gas is adsorbed to graphene of the OFET to change a work function of graphene, resulting in that a drain current of the organic semiconductor changes. In this case, the current does not flow in graphene, but a channel where the current flows is formed at a gate oxide film just below graphene, resulting in that graphene is heated not so much as the GFET. Accordingly, there is a problem that the variation in the gas sensing becomes large due to the thermal effect as same as the GFET.

### BRIEF DESCRIPTION OF THE DRAWINGS

FIG. 1 is a sectional view illustrating an example of a gas sensor according to an embodiment.

FIG. 2 is a view theoretically illustrating a current change when a capacitance of the gas sensor illustrated in FIG. 1 is found by applying a direct-current voltage.

FIG. 3 is a view illustrating an example of the current changes when the capacitance of the gas sensor illustrated in FIG. 1 is found by applying the direct-current voltage.

FIG. 4 is a view illustrating an example where approximated curves are added to the current changes illustrated in FIG. 3.

FIG. 5 is a view illustrating an equivalent circuit of a series model when the capacitance of the gas sensor illustrated in FIG. 1 is found by applying an alternating voltage.

FIG. 6 is a view illustrating an equivalent circuit of a parallel model when the capacitance of the gas sensor illustrated in FIG. 1 is found by applying the alternating voltage.

FIG. 7 is a view illustrating a calculation example of a capacitor's capacitance when gas is supplied to the gas sensor illustrated in FIG. 1.

FIG. 8 is a view illustrating another calculation example of the capacitor's capacitance when gas is supplied to the gas sensor illustrated in FIG. 1.

FIG. 9 is a view illustrating a calibration curve of the capacitor's capacitance with respect to a gas concentration supplied to the gas sensor illustrated in FIG. 1.

FIG. 10 is a view illustrating an example where a drain current change is detected in a conventional graphene FET.

FIG. 11 is a view illustrating an example where a capacitance change in the gas sensor of the embodiment is detected.

FIG. 12 is a view illustrating a band structure of the capacitor in the gas sensor of the embodiment.

FIG. 13 is a view illustrating a change in a band structure of graphene.

FIG. 14 is a view illustrating a change of the band structure of graphene when gas is adsorbed.

FIG. 15 is a sectional view illustrating another example of the gas sensor of the embodiment.

FIG. 16 is a sectional view illustrating still another example of the gas sensor of the embodiment.

FIG. 17 is a view illustrating a measurement flow of a gas concentration using the gas sensor of the embodiment.

FIG. 18 is a view illustrating a configuration example of a gas sensing system using the gas sensor of the embodiment.

FIG. 19 is a view illustrating an example of an organic probe provided at graphene of the gas sensor of the embodiment.

FIG. 20 is a view illustrating a calculation example of a capacitor's capacitance when gas is supplied to the gas sensor including the organic probe illustrated in FIG. 19.

FIG. 21 is a view illustrating a calculation example of the capacitor's capacitance when gas is supplied to the gas sensor including the organic probe illustrated in FIG. 19.

### DETAILED DESCRIPTION

A gas sensing method of an embodiment includes: a step of supplying measured gas to a capacitor including a first electrode, a dielectric formed to be electrically connected to the first electrode, a graphene formed on the dielectric, and a second electrode formed to be electrically connected to the graphene; and a step of measuring a capacitance of the capacitor after the measured gas is brought into contact with the graphene.

Hereinafter, there will be explained a gas sensing method, a gas sensor, and a gas sensing system according to embodiments with reference to the drawings. In the embodiments, substantially the same constituent elements are denoted by the same reference signs and an explanation thereof will be omitted in some cases. The drawings are schematic, and a relation of the thickness and the planar dimension of each part, a thickness ratio of each part, and so on may differ from actual ones.

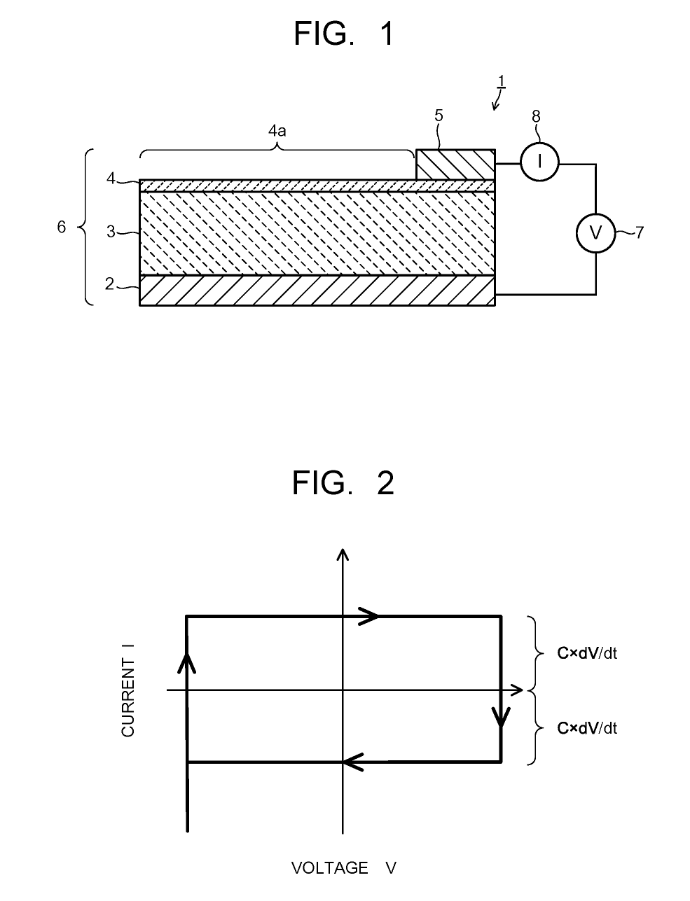

FIG. 1 is a sectional view illustrating a constitution of a gas sensor according to an embodiment. A gas sensor 1 illustrated in FIG. 1 includes: a capacitor 6 having a first electrode 2, a dielectric 3 formed on the first electrode 2, a graphene 4 formed on the dielectric 3, and a second electrode 5 formed to be in contact with a part of the graphene 4; a power supply 7 to apply voltage between the first electrode 2 and the second electrode 5; and an ammeter 8 measuring a current flowing between the first electrode 2 and the second electrode 5. The dielectric 3 may be formed to be electrically connected to the first electrode 2, and the second electrode 5 may be formed to be electrically connected to the graphene 4. The second electrode 5 is provided on a part of the graphene 4 such that at least a part of the graphene 4 exposes as a gas adsorption area (gas sensing area) 4a.

In the gas sensor 1 illustrated in FIG. 1, a capacitance between the first electrode 2 and the second electrode 5 is measured when measured gas is adsorbed to the gas adsorption area 4a of the graphene 4. The measured gas is adsorbed to the graphene 4 resulting in that a capacitance of the capacitor 6 changes, and the measured gas is sensed by using the capacitance change. A capacitance of the capacitor 6 can be found by measuring a minute electric current and a phase thereof between the first electrode 2 and the second electrode 5. At this time, the current seldom flows in the graphene 4. Accordingly, temperature rise due to the graphene 4 being heated can be prevented, and a change in device characteristics of the capacitor 6 resulting from the temperature rise can be prevented. Further, desorption of a residual solvent and adsorbed gas in the air due to the temperature rise of the graphene 4 can also be prevented. As a result, factors causing variation and error in measurement values are reduced, to increase measurement accuracy of the measured gas by the gas sensor 1.

The capacitance of the capacitor 6 is measured by applying a direct-current voltage between the electrodes 2, 5, or by applying an alternating voltage between the electrodes 2, 5. First, a method measuring the capacitance by applying the direct-current voltage is described. The direct-current voltage is changed at a constant rate, and the capacitance is found from a current change (displacement current) at that time. An electric charge accumulated at the dielectric 3 sandwiched between the two electrodes 2, 5 is set as Q, and the capacitance is set as C, then a current I measured when a voltage V is changed is represented by the following expression (1).

Q=CV

I=dQ/dt=dC/dt×V+C×dV/dt (1)

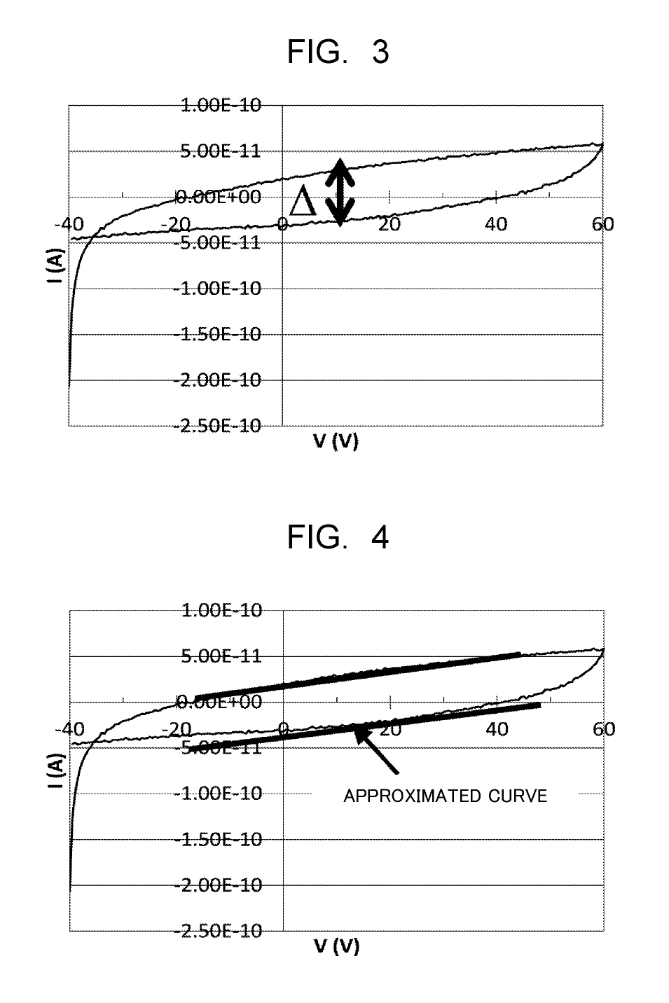

When the voltage V is dual-scanned at a constant rate from minus to plus, and then to minus, where C does not change during the sensing (dC/dt=0), the current change becomes the state as illustrated in FIG. 2, a difference I between scanning in a (+) direction and scanning in a (−) direction is measured, the resultant is divided by a scanning rate of V and reduced to half, and the capacitance C is obtained. Actual measurement values are as illustrated in FIG. 3. When C is assumed to be constant (dC/dt=0), a current difference (ΔI) between the scanning in the (+) direction and the scanning in the (−) direction is divided by the scanning rate of the voltage V and reduced to half, then C is found. As illustrated in FIG. 4, an approximated curve is drawn to each of curves of the scanning in the (+) direction and the scanning in the (−) direction by using a linear approximation, and thereby, an error resulting from measurement variation can be reduced. The difference I between the scanning in the (+) direction and the scanning in the (−) direction is divided by the scanning rate of V and reduced to half when the voltage V is 0 V, then C can be found.

Concretely, it is possible to supply a direct-current power supply to the two electrodes 2, 5 and measure a current value between the electrodes by connecting the two electrodes 2, 5 of the capacitor 6 sandwiching the graphene 4 and the dielectric 3 to, for example, terminals of a semiconductor parameter analyzer. A capacitance calculation can be made as described above by using the measurement value.

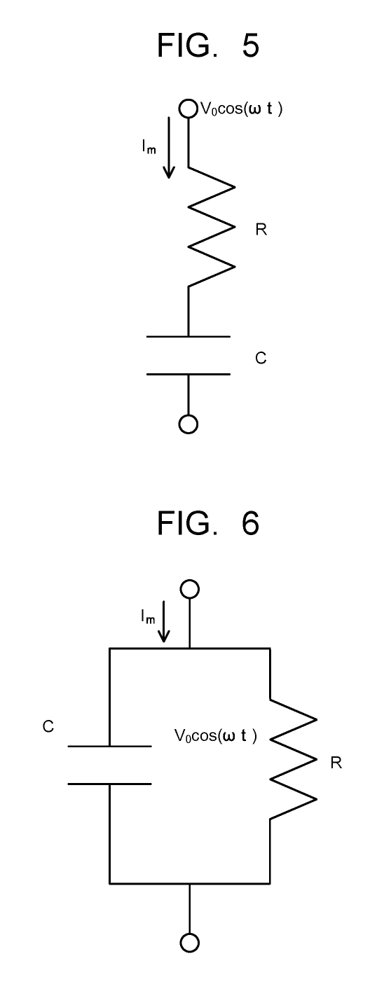

Next, a method measuring the capacitance by applying the alternating voltage is described. When an angular frequency of the alternating voltage (when a frequency of the alternating voltage is set to f, the angular frequency is 2πf) is set to ω, the alternating voltage is described as V₀ cos(ωt). When the capacitance is found by using the alternating voltage, capacitance measurement is performed by using a series model or a parallel model according to a material and a parasitic resistance of the dielectric 3. In case of the series model, an equivalent circuit as illustrated in FIG. 5 is used. When a measurement current at this time is set to Iₘ the following expression is established.

Iₘ=−CV₀ω/[√{1+(CRω)²}]sin(ωt−δ)

tan δ=CRω

C and R can be found from an absolute value and a phase δ of the measurement current Iₘ.

In case of the parallel model, an equivalent circuit as illustrated in FIG. 6 is used. When the measurement current at this time is set to Iₘ, the following expression is established.

Iₘ=−V₀√{(1/R)²+(Cω)²}cos(ωt+δ)

tan δ=CRω

C and R can be found from an absolute value and a phase δ of the measurement current Iₘ.

As the measurement methods of the above-stated C and R, there can be cited a simple method where a phase is detected by an oscilloscope, and an absolute value of the current is measured by a current probe. There are a bridge method, an auto-balancing bridge method, an I-V method, an RF-I-V method, a network analysis method, and so on, and they can be properly used according to accuracy, a measurement frequency, and a sample. A commercially available measuring device can be used as for an impedance measuring device (LCR meter) using the auto-balancing bridge method, the RF-I-V method, and the network analysis method, and C can be measured by using the above.

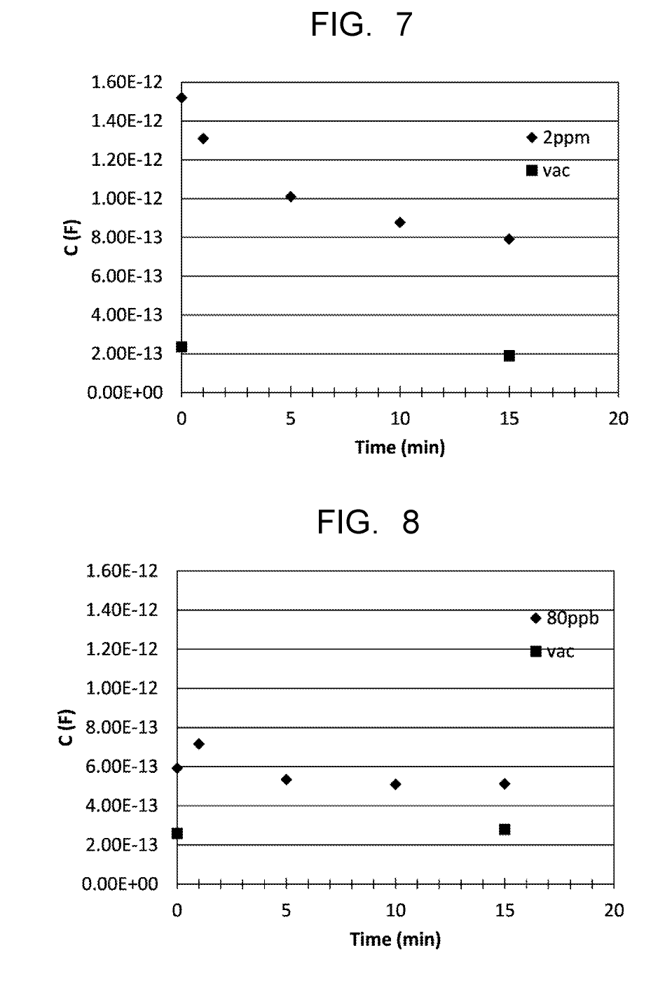

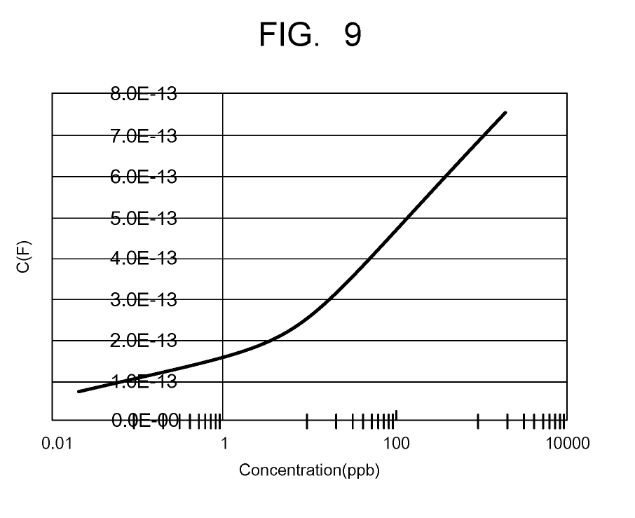

Next, an example measuring gas by using the above-stated gas sensor 1 is described. Here, an example using the direct-current voltage is shown. Dimethyl methylphosphonate (DMMP) gas at a concentration of 2 ppm is supplied to the gas sensor 1 set in vacuum, and a change in current I is measured while displacing the direct-current voltage V. The direct-current voltage V is displaced from −40 V to 60 V at 3.3 V/s, (the (+) direction scanning), then displaced from 60 V to −40 V at 3.3 V/s (the (−) direction scanning). A result of calculation of the capacitance from the current difference at this time when V is “0” (zero) V is illustrated in FIG. 7. FIG. 8 is a calculation result of the capacitance when the DMMP concentration is set to 80 ppb. The capacitance in a vacuum is around 2×10⁻¹³ F, but the capacitance increases when DMMP is introduced, and then stabilized. Further, when the DMMP gas is evacuated, the capacitance returns to an original state.

The capacitance change is larger when the concentration of DMMP is 2 ppm than the case when the concentration is 80 ppb, and the capacitance depends on the gas concentration. A calibration curve formed by using an average capacitance from 10 minutes to 15 minutes after the gas is introduced is illustrated in FIG. 9. The concentration can be measured by using the calibration curve from the measured capacitance. It is possible to use the gas sensor 1 for a plural number of times if a vacuum pump is attached because the capacitance increases when the gas is introduced, and returns to the original state by evacuation.

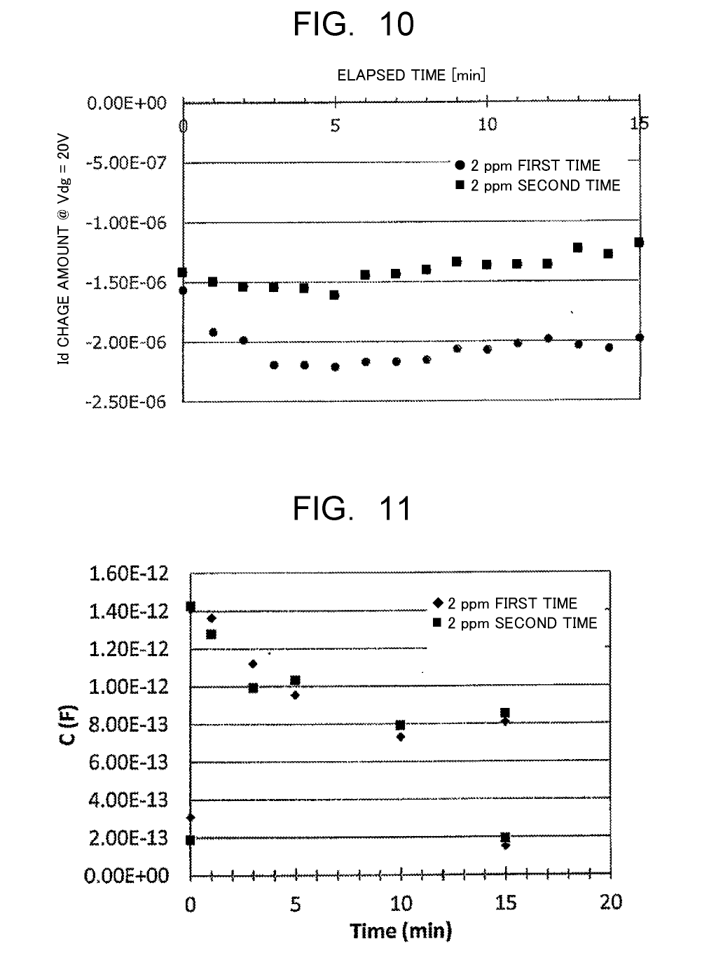

Since a current value flowing in the gas sensor 1 of the embodiment is smaller compared to a method sensing the gas by using Id-Vg (a drain current and a gate voltage) characteristics of a conventional graphene FET, and a method measuring a resistance change at two terminals without a gate electrode, an effect of a history observed when the sensing is performed for a plurality of number of times becomes small. Actually, a sensing result when after the gas at 2 ppm is introduced, evacuation is performed, and the gas at 2 ppm is introduced again is illustrated in FIG. 10 and FIG. 11. FIG. 10 illustrate an example where a drain current change is detected when a gate voltage of the conventional graphene FET is fixed to 20 V. FIG. 11 illustrate an example where a capacitance change of the gas sensor 1 of the embodiment is detected. Regarding the drain current change, a response in the gas detection at the second time differs from a response at the first time, but similar responses can be obtained regarding the capacitance change, and it can be seen that the gas sensing not affected by the sensing history is achieved.

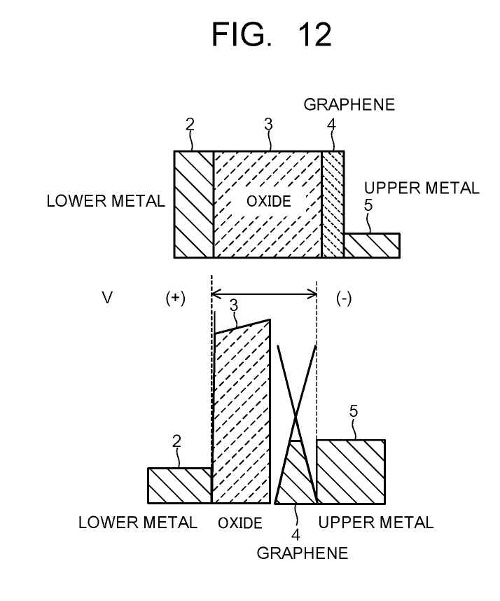

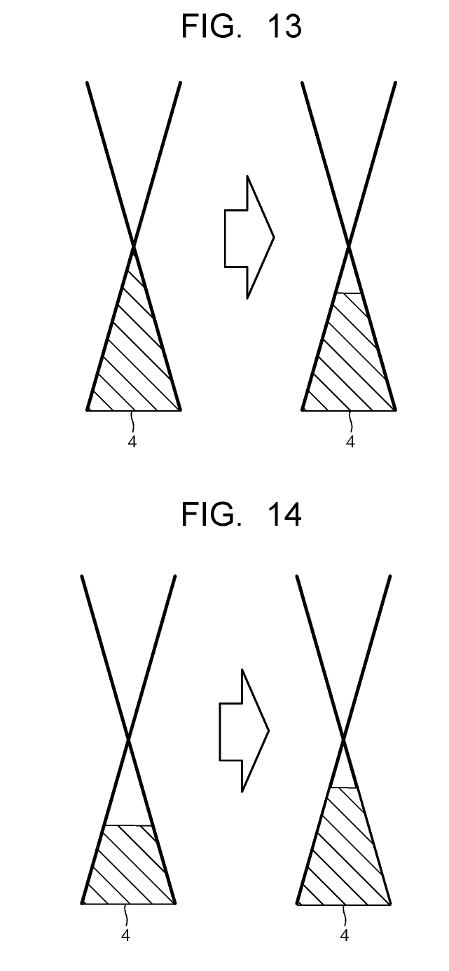

Next, the capacitance change in the gas sensor 1 of the embodiment is described. FIG. 12 illustrates a band structure of the capacitor 6 in the gas sensor 1 of the embodiment. In this example, a positive voltage is applied to the first electrode (lower metal) 2 side. The graphene 4 has a peculiar band structure where there is no band gap, but a density of states becomes almost zero in a vicinity of a Dirac point. A left view in FIG. 13 is the band structure of graphene in an initial state before gas is adsorbed. Under an initial neutral condition, electrons are embedded up to the Dirac point. The graphene 4 in the neutral state is brought into contact with the second electrode (upper metal) 5, resulting in that a Fermi-level of the graphene 4 becomes the same as a Fermi-level of the second electrode (upper metal) 5, and electrons flow from the graphene 4 to the metal 5 (a right view in FIG. 13 and FIG. 12).

The voltage for the above-stated degree is applied between the graphene 4 and the second electrode (upper metal) 5. That is, the voltage applied between the first electrode (lower metal) 2 and the second electrode (upper metal) 5 is a sum of the above-stated voltage between the graphene 4 and the second electrode (upper metal) 5, and effective voltage applied to the capacitor 6 where an oxide film is the dielectric 3. A change in the band structure of graphene when the gas is adsorbed is illustrated in FIG. 14.

FIG. 14 illustrates a case when electrons are given from the graphene 4 to gas molecules (a left view in FIG. 14). In the case that the gas is adsorbed, the Fermi-level of the graphene 4 and the Fermi-level of the second electrode (upper metal) 5 become the same when the graphene 4 and the second electrode (upper metal) 5 are brought into contact, and electrons flow from the second electrode (upper metal) 5 to the graphene 4 (a right view in FIG. 14 and FIG. 12). At this time, the effective voltage of the capacitor 6 where the oxide film is the dielectric 3 decreases. Accordingly, electric charges accumulated on the oxide film decreases, and the capacitance decreases.

Next, advantages where the graphene 4 is used for the gas sensor 1 are described. Carbon nanotubes and graphite are known as nanocarbons in addition to graphene. Graphene is a two-dimensional substance where six-membered rings of carbon are formed in a sheet shape in one layer. Though there is no band gap, the density of states linearly changes in the vicinity of the Dirac point, and to be zero at the Dirac point. The neutral condition of graphene is a state where electrons are embedded up to the Dirac point, resulting in that the Fermi-level changes due to slight transfer of electrons and holes. When electron transfer occurs due to the gas adsorption, the Fermi-level largely changes. 100441 The carbon nanotube (a single-wall carbon nanotube: SWCNT) is one where a sheet made up of six-membered rings of carbon becomes a ring to form a hollow tube.

There are a metallic SWCNT and a semiconductor SWCNT, but the semiconductor SWCNT contributes to the gas sensing. Since the SWCNT is the semiconductor, a junction between the semiconductor and the metal is established in case of the junction with the electrode, resulting in that a depletion-layer capacitance is generated depending on a voltage direction, and capacitances other than the gas sensing are added to the measured capacitances. In a band structure of the semiconductor SWCNT, change in a density of states in a radial direction is the same as graphene, but a density of states in a tube longitudinal direction is higher than graphene, and a Fermi-level-change of the CNT in electron transfer due to the gas molecule adsorption is smaller than that of graphene.

Graphite is formed by stacking sheets where the six-membered rings of carbon are arranged to be a bulk structure. Graphite is a semimetal where bands are overlapped with each other, and has conductivity. Since graphite has a sufficient density of states in a vicinity of a Fermi-level, the Fermi-level-change of graphite in the electron transfer due to the gas molecule adsorption is smaller than those of graphene and CNT.

As stated above, it can be thought that the Fermi-level of graphene sensitively changes with respect to the gas molecule adsorption owing to the band structure, the measured capacitance change is large, and sensitivity is high compared to other nanocarbons. Accordingly, it is possible to enable high-sensitive gas sensing according to the gas sensor 1 using the graphene 4.

There is also the following difference between cases when the SWCNT is used and graphene is used for the gas sensing part. The CNT has a tubular shape. Accordingly, when the CNTs are formed on the dielectric, tubes are arranged horizontally, and it is difficult to densely arrange the CNTs into one layer. Parts where the dielectric exposes and the CNTs are overlapped are inevitably formed also at the sensor part. At the part where the CNTs are overlapped, walls of the CNTs are overlapped and the CNTs approximate to be graphite. As stated above, since the density of states in the vicinity of the Fermi-level becomes high, the sensing sensitivity decreases because a potential change becomes small compared to the part where the CNTs are not overlapped under the same gas adsorption amount. At the part where the dielectric is exposed, the gas enters the dielectric to change a dielectric constant. Accordingly, both the dielectric constant where gas is polarized by the CNTs and the dielectric constant where the dielectric constant of the dielectric is changed are measured. In addition, since the dielectric constant changes due to the gas entering the dielectric, it takes a time until a signal is stabilized, which deteriorates the responsiveness.

Meanwhile, graphene has a sheet shape originally, the sensing part can be covered. Further, graphene does not transmit gas. The dielectric constant change of the dielectric at a lower layer due to the gas adsorption is thereby prevented, and it is possible to enable the gas sensor 1 having good responsiveness and capable of measuring the gas concentration with high sensitivity.

The CNT is the semiconductor, so that the CNT has low conductivity and high resistance. Meanwhile, graphene has a very high mobility within the sheet, high conductivity, and low resistance. The voltage applied to the electrode can be regarded to be applied to the series of the resistor made of the CNT or graphene and a capacitor made of the dielectric. In view of the responsiveness, when the gas is adsorbed, a response speed of graphene is faster than that of the CNT because the response speed is faster as the resistance is smaller when the capacitance is the same.

It is ideally possible for the graphene 4 to cover the gas sensing area (the fabricated area of a graphene sheet) of the dielectric 3 for 100%, but actually, there is a case when a part of the graphene sheet is broken when the capacitor 6 is fabricated. A coverage of the graphene 4 at the gas sensing area of the dielectric 3 is preferably 95% or more in consideration of a function of the graphene 4 as a barrier layer with respect to the dielectric 3. The high-sensitive gas sensor 1 can be enabled as stated above even when the coverage of the graphene 4 is less than 95%.

The coverage of the graphene 4 can be observed with an optical microscope depending on a film thickness of the dielectric 3 under the graphene. For example, graphene can be identified with the optical microscope on a Si thermal oxide film, of which the thickness is a vicinity of 285 nm, and the coverage can be found. Since film thickness measurement is possible with an atomic force microscope (AFM), the coverage can be found by AFM. Graphene can be observed also with a scanning electron microscope (SEM) and a transmission electron microscope (TEM), and the coverage can be found by SEM and TEM.

The graphene 4 can be obtained by, for example, peeling a highly-oriented pyrolytic graphite (HOPG) to be a single layer (for example, a peeled graphene made by a Scotch tape method), but graphene fabricated by a chemical vapor deposition (CVD) method enables efficient device fabrication. As a fabrication method of CVD graphene, there can be exemplified a method where a Cu foil is used as a catalyst, raw gas such as methane and hydrogen is supplied at high temperature to once dissolve a carbon source into Cu, and then cooled to precipitate graphene.

Graphene is originally in one layer, but since CVD graphene achieve crystal growth from a precipitated nucleus, graphene is likely to be polycrystal. As a result, graphene is not necessarily a single layer, and there is a case when a several layers are overlapped, or the dielectric is not completely covered. The identification of graphene is usually performed by Raman spectrum. Graphene is identified from an intensity ratio (I_{2D}/I_{G}) between a G band around 1590 cm⁻¹ and a 2D band around 27680 cm⁻¹. In CVD graphene, a value of I_{2D}/I_{G} of one or less is usually identified as graphene in the context that there is no breakage, and covered, and the number of layers is approximately five layers or less. Graphene comes like graphite if the total number of six-membered ring sheets of carbon increases, resulting in that the high-sensitivity and high-responsiveness like the gas sensor 1 of the embodiment cannot be expected. Accordingly, the number of layers of graphene is desirably five layers or less where graphene is experimentally identifiable, and the high-sensitivity and high-responsiveness can be kept.

When graphene is fabricated by the CVD method, other metals such as Ni and Pt can be used as the catalyst instead of Cu. Hydrogenated Ge can also be used as the catalyst. However, the number of layers is likely to increase compared to the case when

Cu is used as the catalyst. In such cases, these metals can be used similarly as long as the value of I_{2D}/I_{G} is one or less in the Raman spectrum. CVD graphene can be fabricated also on an SiC substrate. Since it is necessary to dissolve a catalyst layer to fabricate a device, CVD graphene fabricated on the Cu foil which is cheaper than SiC is often used, but CVD graphene fabricated on the SiC substrate can also be used.

In the gas sensor 1 of the embodiment, noble metals such as Au, Pd, Ag, Pt can be used as materials of the first and second electrodes 2, 5. Further, the second electrode 5 may be formed by depositing Ni or Cr as a lower layer, and then vapor-depositing the noble metal in order to improve adhesiveness with the graphene 4 and the dielectric 3. The case when the dielectric 3 is formed on the first electrode 2 is also the same, and the dielectric 3 may be formed after Ni or Cr is deposited as a lower layer.

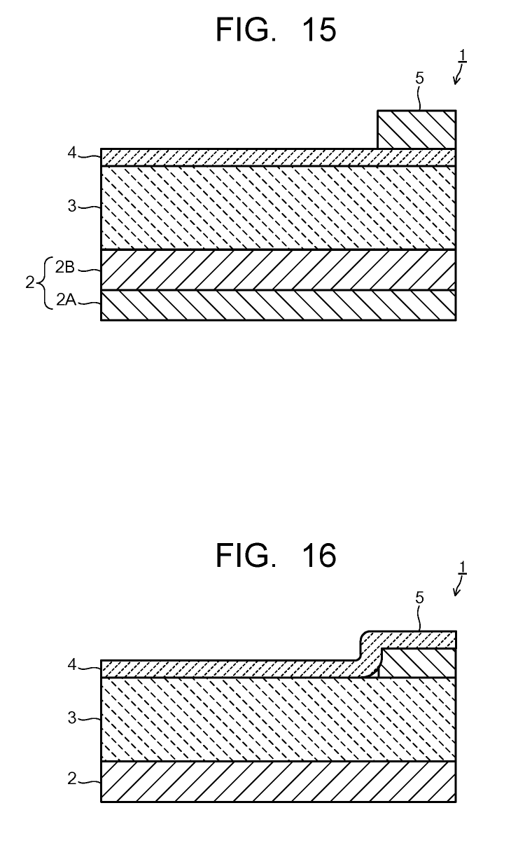

The first electrode (lower electrode) 2 is not limited to the metal, but, for example, a stacked film made of a metal film 2A and a highly-doped Si film 2B may be used as the electrode 2 as illustrated in FIG. 15. When the highly-doped Si film 2B is n-type, the metal film 2A is preferably made to be a film where a metal with small work function, for example, Ti and the noble metal are stacked, in order to avoid a Schottky junction. When the highly-doped Si film 2B is p-type, the metal film 2A may usually be only the noble metal though it depends on the work function of the noble metal. The highly-doped Si film 2B is used to enable an ohmic contact, and the film functions as the electrode 2. A structure described in aforementioned Patent Document 2 is not the highly-doped Si but a p-type semiconductor and an n-type semiconductor, and it is different from the structure illustrated in FIG. 15. According to the structure described in Patent Document 2, electric charges are accumulated in a depletion layer in a p-n junction, and a depletion-layer capacitance is further added, resulting in that the capacitance measurement is difficult.

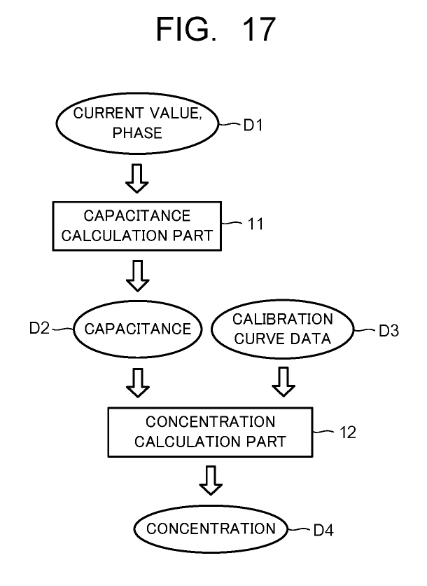

FIG. 1 illustrates the example where the second electrode 5 is formed on the graphene 4, but the structure is not limited thereto. The second electrode 5 is only to be in contact with the graphene 4. Accordingly, the graphene 4 may be formed on the second electrode 5 as illustrated in FIG. 16. Also in this case, the similar effect can be expected because electric lines of force pass through the graphene 4 and an electric field is applied. Though three electrodes of a gate electrode, a source electrode, and a drain electrode are necessary in case of a graphene FET, only the two electrodes of the first electrode (lower electrode) 2 and the second electrode (upper electrode) 5 are necessary to be held because the gas sensor 1 of the embodiment is to detect the gas by measuring the capacitance, and the capacitance is measured by using these electrodes 2, 5.

In the gas sensor 1 illustrated in each of FIG. 1, FIG. 15, and FIG. 16, an Si oxide is cited as a representative example of the dielectric 3, and the above-stated measurement results are also the results using the Si oxide, but the dielectric 3 is not limited to the Si oxide. The dielectric 3 of the gas sensor 1 may be an Hf oxide, an Al oxide, further F and C are added to the Si oxide, or a polymer.

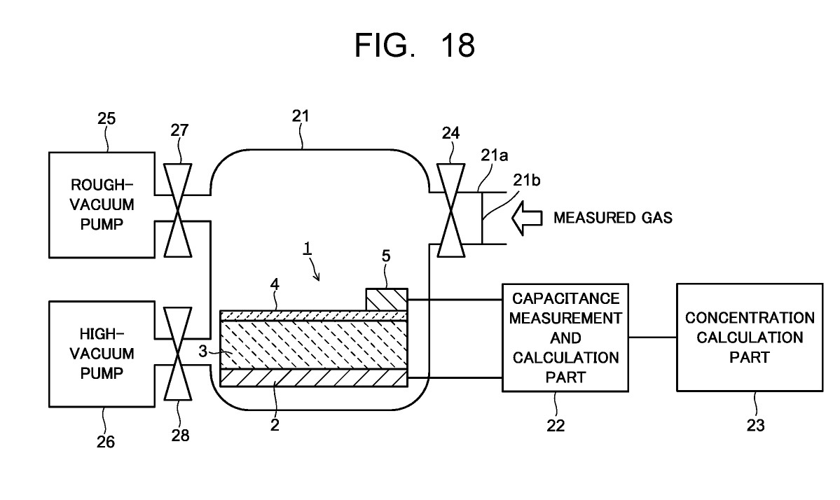

Next, a measurement flow of a gas concentration using the gas sensor 1 is described with reference to FIG. 17. FIG. 17 is a flow calculating a gas concentration from a measured current value and phase. A measured current value and phase D1 is transmitted to a capacitance calculation part 11. The capacitance is calculated at the capacitance calculation part 11 from the current value and the phase (in case of the alternating voltage). A calculation result D2 of the capacitance is transmitted to a concentration calculation part 12, and a calibration curve data (for example, FIG. 9) D3 being a relation between a concentration and a capacitance of measured gas which is measured in advance is transmitted from a not-illustrated storage part to the concentration calculation part 12. At the concentration calculation part 12, the calculation result D2 of the capacitance is compared with the calibration curve data D3, to thereby find a concentration D4.

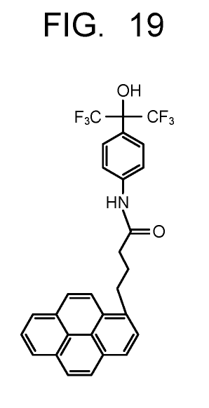

A configuration example of a gas sensing system using the gas sensor 1 is described with reference to FIG. 18. The gas sensor 1 is disposed in a gas chamber 21. The first and second electrodes 2, 5 of the gas sensor 1 are connected to a capacitance measurement and calculation part 22 such as a semiconductor parameter analyzer (in case of a direct-current voltage) or an LCR meter (an impedance measuring device, in case of an alternating voltage) each including a power supply and an ammeter. The capacitance as a measurement and calculation result is transmitted to a concentration calculation part 23, and a concentration is calculated based on the flow (in case of the alternating voltage) or the like illustrated in FIG. 17.

The graphene 4 is likely to be contaminated, and reactivity is lowered if the graphene 4 is let stand in the air. The graphene 4 is therefore preferably sealed in vacuum before it is used. Accordingly, the gas sensor 1 is sealed in vacuum by the gas chamber 21. The vacuum-sealing of the gas chamber 21 is broken to introduce measured gas when it is used, and thereby, an accurate measurement is enabled. As a breaking method of the vacuum-sealing, an opening is formed at a vacuum sealing wall 21b provided at a gas inlet port 21a of the gas chamber 21 with an opening jig to fabricate an opening such as, for example, a cone, or a file or the like when the vacuum sealing wall 21b is made of glass. A valve 24 provided at the gas inlet port 21a is previously opened. The gas sensor 1 is able to obtain higher accuracy and higher responsiveness by introducing gas from a vacuum-sealing state at the usage time.

Reuse of the gas sensor 1 becomes possible by attaching a vacuum pump to the gas chamber 21, and providing the valve 24 on the gas chamber 21 side at the back of the vacuum sealing wall 21b. As illustrated in FIG. 11, the responsiveness is restored when the gas sensor 1 is once returned to vacuum. A rough-vacuum pump 25 which evacuates gas with an approximately atmospheric pressure after the sensing and a high-vacuum pump 26 which keeps high-vacuum subsequently are preferably held as the vacuum pumps. The rough-vacuum pump 25 and the high-vacuum pump 26 are connected to the gas chamber 21 through valves 27, 28, respectively.

A diaphragm pump and a rotary pump can be used as the rough-vacuum pump 25. A turbo molecular pump and an adsorption pump (an ion pump and a cryopump) can be used as the high-vacuum pump 26. Since the turbo molecular pump has the diaphragm pump or the rotary pump at a post-stage thereof, the diaphragm pump or the rotary pump may be used as the rough-vacuum pump 25 of the gas chamber 21 by being separated from the high-vacuum pump using a valve. The vacuum pump may be a dry pump. The vacuum pumps 25, 26 are divided off from the gas chamber 21 by the valves 27, 28, and the valves 27, 28 are set to be closed states at a gas sensing time, and the valves 27, 28 are set to be open states at an evacuation time.

In the aforementioned gas sensing system, it is assumed that the measured gas is measured as it is, but the gas may be concentrated and then supplied to the gas sensing system. Higher accuracy measurement becomes possible by supplying the gas after concentration. Further, higher accuracy measurement becomes possible if gases obstructing the sensing are previously removed with a filter or the like.

The above-stated explanation describes a case when the gas sensing is performed by using only the graphene 4, but the gas sensing is not limited thereto. For example, it is possible to measure the concentration of each gas species by fixing molecules each having a group reacting with the measured gas, for example, an organic probe at a surface of the graphene 4, and making the gas selectively react with the probe as it is described in Japanese Patent Application No. 2017-534026. The organic probe can be fixed to the graphene 4 through a method using a pyrene ring to fix by a π-π bonding with the graphene 4 as it is described in, for example, Japanese Patent Application No. 2017-534026, a method coating a polymer having a group which selectively reacts with gas such as a chemoselective polymer HC described in E. S. Snow et al., Science 307(2005)1942, a method coating nano-metal particles having a group selectively reacting with the gas, and so on.

A case when the gas is DM:MP is explained as an example, but the gas is not limited to DM:MP, and measurement is possible as long as it is the gas, of which the adsorption to grapheme induces capacitance change. Further, measurement is also possible when not graphene independently but a probe, a nano-metal particle, or a polymer each having a group reacting with the measured gas are formed at the graphene surface to make the gas selectively react with the probe. Examples of the gas include H₂O, NH₃, NO, NO₂, CO, CO₂, methane, ethane, propane, butane, acetylene, CF₄, CHF₃, C₂F₆, C₃F₈, C₄F₁₀ where H is replaced by F, and so on. Phosphoric acid-based gas belonging to the same series as DMMP, sarin, soman, tabun, agricultural chemicals, methanephetamine, amphetamine, cocaine being illicit drugs, and the like can be also measured.

Next, there is described a method performing concentration measurement by introducing a group reacting with gas into a pyrene derivative and utilizing reactivity thereof as an example of the method performing the gas sensing by fixing the probe having the group reacting with the measured gas to the surface of the graphene 4, and making the gas selectively react with the probe. The measured gas is DMMP, and a pyrene derivative illustrated in FIG. 19 is used as the sensing probe. It is thought that an OH group held by the probe and DMMP are hydrogen bonded to cause transfer of electric charges. Probe molecules are dissolved in methanol, and the concentration is adjusted to 1 mM. A methanol solution of the probe is dropped on the graphene 4 of the gas sensor 1 and left at rest for one hour. The π-π bonding is formed between the pyrene ring of the probe and the graphene 4 during one hour, and the probe molecules are fixed. After that, excessive probe molecules are washed with methanol, and the resultant is dried to form the probe.

A solvent where the pyrene derivative of the probe is dissolved may be selected as a probe forming solvent, and it is not limited to methanol. A probe solution concentration is set to 1 mM in this example, but it can be appropriately adjusted according to a kind of the probe and a solvent. In this example, the probe solution concentration of 1 mM is selected because a capacitance increases as the probe solution concentration is increased, and the capacitance is saturated when the concentration is 1 mM or more. It is thought that the capacitance increases because the gas and the probe selectively react. Since the capacitance is saturated when the probe solution concentration is 1 mM or more, it can be thought that the surface of the graphene 4 is almost covered with the probe molecules.

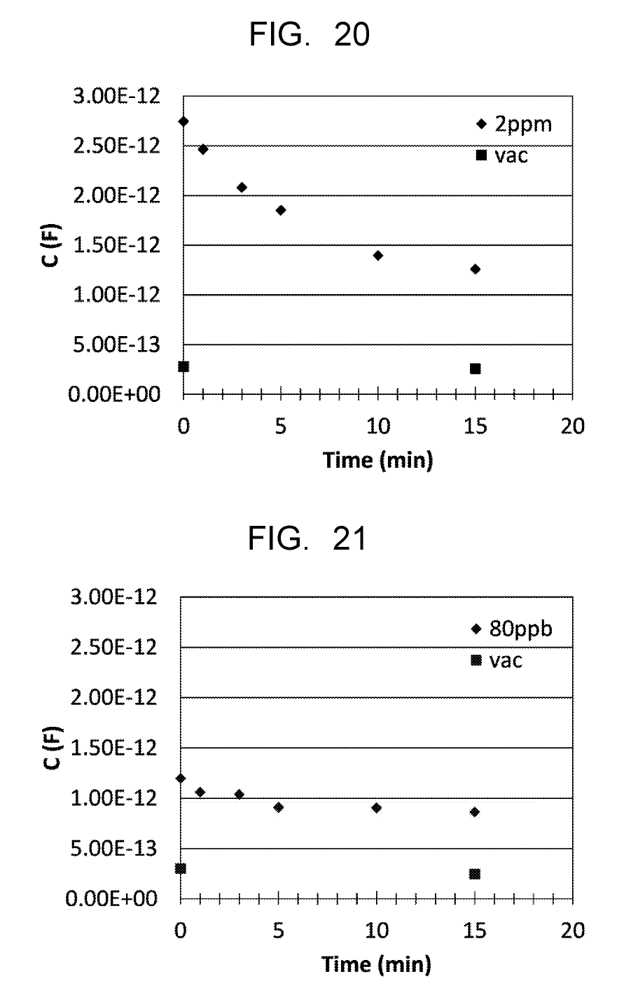

The sensor formed as stated above is put into a vacuum device, and after evacuation, DMMP is introduced into the device to perform the gas sensing. A capacitance change when DMIMP at 2 ppm is introduced is illustrated in FIG. 20, and a capacitance change when DMIMP at 80 ppb is introduced is illustrated in FIG. 21. As same as the case of using only the graphene 4, the capacitance increases when the gas is introduced, and returns to the original state when evacuated. The capacitance is larger when the concentration is 2 ppm than the case when it is 80 ppb. Since the gas concentration and the capacitance are correlated, the gas concentration can be specified from the measured capacitance by forming a calibration curve similar to one in FIG. 9.

As described above, the gas sensing method and the gas sensing system of the embodiment can be applied to not only the case when the gas is adsorbed to the graphene 4 but also the case when the probe having the group reacting with the measured gas is formed at the surface of the graphene 4. An electric potential which changes due to a reaction between the gas and the probe molecules can be measured as a capacitance with high sensitivity and high accuracy. The measured gas is not limited to one kind. For example, a probe, a nano-metal particle, or a polymer whose reacting groups are different by each gas are formed on graphene, a plurality of gas sensors 1 corresponding to the gases are disposed in an array state, and identification and concentration measurement of a plurality kinds of gases can be simultaneously performed by using reaction patterns.

While certain embodiments of the present invention have been described, these embodiments have been presented by way of example only, and are not intended to limit the scope of the inventions. Indeed, the novel embodiments described herein may be embodied in a variety of other forms; furthermore, various omissions, substitutions and changes may be made without departing from the spirit of the inventions. The inventions described in the accompanying claims and their equivalents are intended to cover such forms or modifications as would fall within the scope and spirit of the inventions.

What is claimed is:

1. A gas sensing method, comprising:
supplying measured gas to a capacitor including a first electrode, a dielectric formed to be electrically connected to the first electrode, a graphene formed on the dielectric, and a second electrode formed to be electrically connected to the graphene; and
measuring a capacitance of the capacitor after the measured gas is brought into contact with the graphene.

2. The method according to claim 1, wherein
the capacitance measuring comprises calculating the capacitance from a current change flowing between the first electrode and the second electrode by applying a direct-current voltage between the first electrode and the second electrode and scanning a voltage of the first electrode at a constant rate.

3. The method according to claim 1, wherein
the capacitance measuring comprises calculating the capacitance from a phase and an absolute value of a measured current by applying an alternating voltage between the first electrode and the second electrode.

4. The method according to claim 1, wherein
the capacitor includes molecules each having a group specifically reacting with the measured gas on the graphene.

5. A gas sensor, comprising:
a capacitor which includes: a first electrode; a dielectric electrically connected to the first electrode; a graphene formed on the dielectric; and a second electrode electrically connected to the graphene;
a power supply to apply a voltage between the first electrode and the second electrode; and
an ammeter to measure a current between the first electrode and the second electrode.

6. The sensor according to claim 5, wherein
the power supply is a direct-current power supply applying a direct-current voltage between the first electrode and the second electrode, and
the ammeter comprises a circuit to scan a voltage of the first electrode at a constant rate when the direct-current voltage is applied, and to detect a current change flowing between the first electrode and the second electrode, and a circuit to find a capacitance of the capacitor from the current change.

7. The gas sensor according to claim 5, wherein
the power supply is an alternating-current power supply applying an alternating voltage between the first electrode and the second electrode, and
the ammeter comprises a circuit to detect an absolute value and a phase of a current between the first electrode and the second electrode when the alternating voltage is applied, and a circuit to find a capacitance of the capacitor from the absolute value and the phase of the current.

8. The gas sensor according to claim 5, wherein
the graphene is provided to cover 95% or more of a gas sensing area of the dielectric.

9. The gas sensor according to claim 5, wherein
the capacitor includes five layers or less of the graphene.

10. The gas sensor according to claim 5, wherein
the capacitor includes molecules each having a group specifically reacting with measured gas on the graphene.

11. A gas sensing system, comprising:
the gas sensor according to claim 6;
a gas chamber where the gas sensor is disposed, and measured gas is introduced;
a capacitance calculation part which calculates a capacitance of the capacitor of the gas sensor from a current value measured by the ammeter of the gas sensor; and
a concentration calculation part which calculates a concentration of the measured gas from the calculated capacitance by using a correlation between a concentration of the measured gas prepared in advance and the capacitance of the capacitor.

12. The gas sensing system according to claim 11, wherein
the gas chamber includes a mechanism capable of vacuum-sealing, and bringing the measured gas into contact with the gas sensor by breaking the vacuum-sealing at a measurement time.

13. The gas sensing system according to claim 11, wherein
the gas chamber includes a vacuum pump which evacuates an inside of the gas chamber.

14. A gas sensing system, comprising:
the gas sensor according to claim 7;
a gas chamber where the gas sensor is disposed, and measured gas is introduced;
a capacitance calculation part which calculates a capacitance from a current value and a phase measured by the ammeter of the gas sensor; and
a concentration calculation part which calculates a concentration of the measured gas from the calculated capacitance by using a correlation between a concentration of the measured gas prepared in advance and the capacitance of the capacitor.

15. The gas sensing system according to claim 14, wherein
the gas chamber includes a mechanism capable of vacuum-sealing, and bringing the measured gas into contact with the gas sensor by breaking the vacuum-sealing at a measurement time.

16. The gas sensing system according to claim 14, wherein
the gas chamber includes a vacuum pump which evacuates an inside of the gas chamber.
